(19) United States
(12) Patent Application Publication
(10) Pub. No.: US 2022/0173273 A1
(43) Pub. Date: Jun. 2, 2022

(54) MICRO LIGHT-EMITTING DIODE STRUCTURE AND MICRO LIGHT-EMITTING DIODE DISPLAY DEVICE USING THE SAME

(71) Applicant: PlayNitride Display Co., Ltd., Zhunan Township (TW)

(72) Inventors: Yu-Hung LAI, Zhunan Township (TW); Yu-Yun LO, Zhunan Township (TW)

(73) Assignee: PlayNitride Display Co., Ltd., Zhunan Township (TW)

(21) Appl. No.: 17/324,882

(22) Filed: May 19, 2021

(30) Foreign Application Priority Data
Nov. 27, 2020 (TW) 109141748

(51) Int. Cl. H01L 33/38; H01L 27/15

(52) U.S. Cl. CPC H01L 33/382; H01L 27/156

(57) ABSTRACT

A micro light-emitting diode structure is provided. The micro light-emitting diode structure includes a first-type semiconductor layer, a light-emitting layer disposed on the first-type semiconductor layer, and a second-type semiconductor layer disposed on the light-emitting layer. Moreover, the micro light-emitting diode structure includes a first electrode and a second electrode disposed on the top surface of the second-type semiconductor layer and electrically connected to the first-type semiconductor layer and the second-type semiconductor layer, respectively. The first electrode includes two portions, and a rounded corner is formed at the junction therebetween. From the top view of the micro light-emitting diode structure, the light-emitting layer and the second-type semiconductor layer define a mesa region. The area of the mesa region is smaller than the area of the first-type semiconductor layer. The mesa region exposes the first top surface of the first-type semiconductor layer. The first top surface surrounds the mesa region.

### CROSS REFERENCE TO RELATED APPLICATIONS

This application claims priority of Taiwan Patent Application No. 109141748, filed on Nov. 27, 2020, the entirety of which is incorporated by reference herein.

### BACKGROUND

### Technical Field

Embodiments of the present disclosure relate in general to a micro light-emitting diode structure, and in particular they relate to a flip-chip micro light-emitting diode structure.

### Description of the Related Art

With the advancements being made in photoelectric technology, the size of photoelectric components is gradually becoming smaller. Compared to organic light-emitting diodes (OLED), micro light-emitting diodes (micro LED, mLED/μLED) have higher efficiency, longer life, and relatively stable materials that are not as easily affected by the environment. Therefore, displays that use micro light-emitting diodes fabricated in arrays have gradually gained attention in the market.

In a conventional light-emitting diode wafer, one of the electrodes usually needs to be connected to an inner doped semiconductor layer through a plurality of holes that penetrate the insulating layer, the outer doped semiconductor layer, and the light-emitting layer. However, it is difficult to make such holes in a small micro light-emitting diode wafer. Due to the small size of the micro light-emitting diode wafer, the corresponding hole is smaller, and more precise alignment and hole-opening processes are required. Otherwise, short-circuits are caused easily, resulting in a poor overall yield of displays using micro light-emitting diodes.

### SUMMARY

Embodiments of the present disclosure relate to a flip-chip micro light-emitting diode structure. From the top view of the micro light-emitting diode structure, the area of the mesa region is smaller than the area of the first-type semiconductor layer. Moreover, the mesa region exposes a portion of top surface of the first-type semiconductor layer, and the portion of top surface surrounds the mesa region. One electrode of the micro light-emitting diode structure may be electrically connected to the first-type semiconductor layer through the exposed top surface. Therefore, there is no need to make a plurality of aligned holes, which may reduce the complexity of the manufacturing process, effectively prevent short circuits, and improve the overall yield of the display device using the light-emitting diode structure.

Some embodiments of the present disclosure include a micro light-emitting diode structure. The micro light-emitting diode structure includes a first-type semiconductor layer. The micro light-emitting diode structure also includes a light-emitting layer disposed on the first-type semiconductor layer. The micro light-emitting diode structure further includes a second-type semiconductor layer disposed on the light-emitting layer. Moreover, the micro light-emitting diode structure includes a first electrode that has a first portion and a second portion. The first portion is disposed on the top surface of the second-type semiconductor layer, and the second portion connects to the first portion and the first-type semiconductor layer. The first electrode has a rounded corner formed at the junction between the first portion and the second portion. The micro light-emitting diode structure also includes a second electrode disposed on the top surface of the second-type semiconductor layer and electrically connected to the second-type semiconductor layer. From the top view of the micro light-emitting diode structure, the light-emitting layer and the second-type semiconductor layer define a mesa region, and the area of the mesa region is smaller than the area of the first-type semiconductor layer. The mesa region exposes the first top surface of the first-type semiconductor layer, and the first top surface surrounds the mesa region.

Some embodiments of the present disclosure include a micro light-emitting diode display device. The micro light-emitting diode display device includes a display backplane having a first connection electrode and a second connection electrode. The micro light-emitting diode display device also includes the aforementioned micro light-emitting diode structure disposed on the display backplane. The first connection electrode and the second connection electrode are electrically connected to the first electrode and the second electrode, respectively.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a partial cross-sectional view illustrating one stage of manufacturing the micro light-emitting diode structure according to one embodiment of the present disclosure.

FIG. 2 is a partial cross-sectional view illustrating one stage of manufacturing the micro light-emitting diode structure according to one embodiment of the present disclosure.

FIG. 3 is a partial cross-sectional view illustrating one stage of manufacturing the micro light-emitting diode structure according to one embodiment of the present disclosure.

FIG. 4 is a partial cross-sectional view illustrating one stage of manufacturing the micro light-emitting diode structure according to one embodiment of the present disclosure.

FIG. 5 is a partial cross-sectional view illustrating one stage of manufacturing the micro light-emitting diode structure according to one embodiment of the present disclosure.

FIG. 6A is a partial cross-sectional view illustrating one stage of manufacturing the micro light-emitting diode structure according to one embodiment of the present disclosure.

FIG. 6B is a partial cross-sectional view illustrating the micro light-emitting diode structure according to another embodiment of the present disclosure.

FIG. 7 is a partial top view illustrating the micro light-emitting diode structure in FIG. 6A.

FIG. 8 is a partial cross-sectional view illustrating the micro light-emitting diode structure according to another embodiment of the present disclosure.

FIG. 9 is a partial cross-sectional view illustrating the micro light-emitting diode structure according to still another embodiment of the present disclosure.

FIG. 10 is a partial cross-sectional view illustrating the micro light-emitting diode display device according to one embodiment of the present disclosure.

FIG. 11 is a partial circuit diagram of the micro light-emitting diode display device.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In the following, according to some embodiments of the present disclosure, a micro light-emitting diode structure that includes a bonding support layer and a manufacturing method thereof are proposed. By forming the bonding support layer between the pads for connecting the electrodes of the micro-LED, it may effectively prevent the pads from causing a short circuit and prevent the micro-LED from being skew. It may also be used to support the micro-LED and prevent the micro-LED from cracking, and the micro-LED may be more firmly bonded to the substrate.

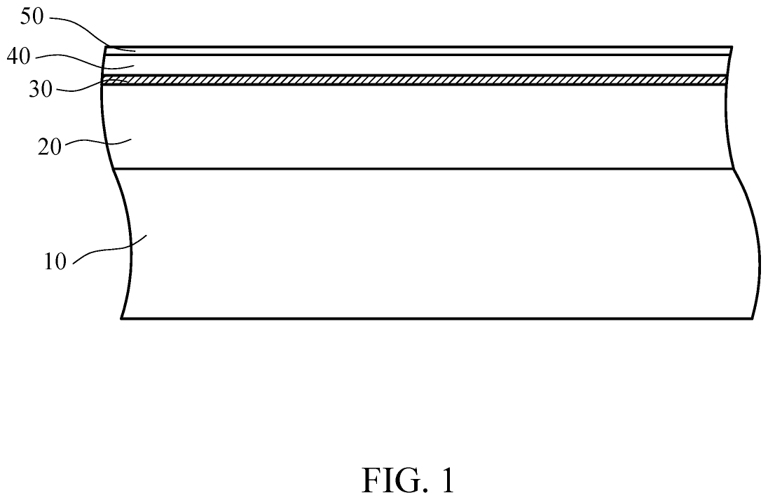

FIGS. 1-6A are partial cross-sectional views illustrating various stages of manufacturing the micro light-emitting diode structure 100 according to one embodiment of the present disclosure. It should be noted that some components may be omitted in FIGS. 1-6A for sake of brevity.

Referring to FIG. 1, a first-type semiconductor material 20, a light-emitting material 30, and a second-type semiconductor material 40 are sequentially formed on a substrate 10. In some embodiments, the first-type semiconductor material 20, the light-emitting material 30, and the second-type semiconductor material 40 may be formed by an epitaxial growth process. For example, the epitaxial growth process may include metal organic chemical vapor deposition (MOCVD), hydride vapor phase epitaxy (HVPE), molecular beam epitaxy (MBE), any other applicable method, or a combination thereof, but the present disclosure is not limited thereto.

In some embodiments, the substrate 10 may be a semiconductor substrate. For example, the material of the substrate 10 may include silicon, silicon germanium, gallium nitride, gallium arsenide, any other applicable semiconductor material, or a combination thereof. In some embodiments, the substrate 10 may be a semiconductor-on-insulator substrate, such as a silicon-on-insulator (SOI) substrate. In some embodiments, the substrate 10 may be a glass substrate or a ceramic substrate. For example, the material of the substrate 10 may include silicon carbide (SiC), aluminum nitride (AlN), glass, or sapphire, but the present disclosure is not limited thereto.

Referring to FIG. 1, the first-type semiconductor material 20 is formed on the substrate 10. In some embodiments, the dopant of the first-type semiconductor material 20 is N-type. For example, the first-type semiconductor material 20 may include a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the first-type semiconductor material 20 may include dopants such as silicon (Si) or germanium (Ge), but the present disclosure is not limited thereto. In the embodiments of the present disclosure, the first-type semiconductor material 20 may be a single-layer or multi-layer structure.

Referring to FIG. 1, the light-emitting material 30 is formed on the first-type semiconductor material 20. In some embodiments, the light-emitting material 30 may include at least one undoped semiconductor layer or at least one low-doped layer. For example, the light-emitting material 30 may be a quantum well (QW) layer, which may include indium gallium nitride (InₓGa₁₋ₓN) or gallium nitride (GaN), but the present disclosure is not limited thereto. In some embodiments, the light-emitting material 30 may also be a multiple quantum well (MQW) layer, but the present disclosure is not limited thereto.

Referring to FIG. 1, the second-type semiconductor material 40 is formed on the light-emitting material 30. In some embodiments, the dopant of the second-type semiconductor material 40 is P-type. For example, the second-type semiconductor material 40 may include a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the second-type semiconductor material 40 may include dopants such as magnesium (Mg) or carbon (C), but the present disclosure is not limited thereto. In the embodiment of the present disclosure, the second-type semiconductor material 40 may be a single-layer or multi-layer structure.

As shown in FIG. 1, in some embodiments, a current distribution material 50 may be formed on the second-type semiconductor layer 40. In some embodiments, the current distribution material 50 may be formed on the second-type semiconductor layer 40 by a deposition process. For example, the deposition process may include chemical vapor deposition (CVD), atomic layer deposition (ALD), any other applicable method, or a combination thereof, but the present disclosure is not limited thereto.

In some embodiments, current distribution material 50 may include a transparent conductive material. For example, the transparent conductive material may include indium tin oxide (ITO), tin oxide (TO), indium zinc oxide (IZO), indium gallium zinc oxide (IGZO), indium zinc tin oxide (ITZO), antimony tin oxide (ATO), or antimony zinc oxide (AZO), but the present disclosure is not limited thereto.

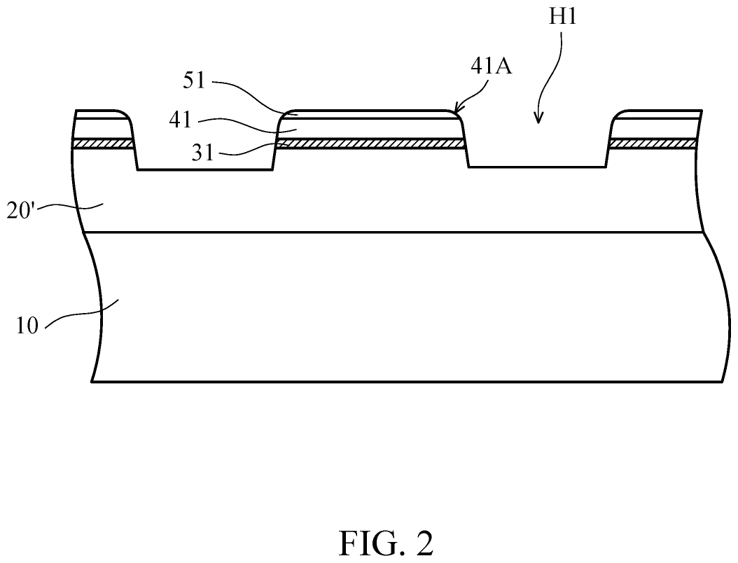

Referring to FIG. 2, a patterning process is performed to form a plurality of trenches H1. In particular, the trenches H1 may divide the light-emitting material 30, the second-type semiconductor material 40, and the current distribution material 50 into a plurality of light-emitting layers 31, second-type semiconductor layers 41, and current distribution layers 51, and form the first-type semiconductor material 20 into a patterned first-type semiconductor material 20′. In some embodiments, a mask layer (not shown) may be provided on the current distribution material 50, and then the mask layer is used as an etching mask to perform an etching process to complete the patterning process.

For example, the mask layer may include a photoresist, such as a positive photoresist or a negative photoresist. In some embodiments, the mask layer may include a hard mask and may include silicon oxide (SiO₂), silicon nitride (SiN), silicon oxynitride (SiON), silicon carbide (SiC), silicon carbonitride (SiCN), the like, or a combination thereof. The mask layer may be a single-layer or multi-layer structure. The mask layer may be formed by a deposition process, a photolithography process, any other applicable process, or a combination thereof. In some embodiments, the deposition process includes spin-on coating, chemical vapor deposition (CVD), atomic layer deposition (ALD), the like, or a combination thereof. For example, the photolithography process may include photoresist coating (e.g., spin coating), soft baking, mask aligning, exposure, post-exposure baking (PEB), developing, rinsing, drying (e.g., hard baking), any other applicable processes, or a combination thereof.

In some embodiments, the aforementioned etching process may include a dry etching process, a wet etching process, or a combination thereof. For example, the dry etching process may include reactive ion etch (RIE), inductively-coupled plasma (ICP) etching, neutral beam etch (NBE), electron cyclotron resonance (ERC) etching, the like, or a combination thereof. For example, the wet etching process may use, for example, hydrofluoric acid (HF), ammonium hydroxide (NH₄OH), or any suitable etchant.

It should be noted that in the embodiment shown in FIG. 2, the patterned first-type semiconductor material 20′ is also under the trenches H1. That is, during the etching process, only the light-emitting material 30, the second-type semiconductor material 40, and the current distribution material 50 and a portion of the first-type semiconductor material 20 are removed in the region to be removed from the aforementioned mask layer, and another portion of the first-type semiconductor material (i.e., the patterned first-type semiconductor material 20′) is still retained, but the present disclosure is not limited thereto. In some other embodiments, during the etching process, the first-type semiconductor material 20 may also be completely retained.

Moreover, in some embodiments, in the cross-sectional view at this stage, the second-type semiconductor layers 41 and the current distribution layers 51 may form a rounded corner. For example, as shown in FIG. 2, each second-type semiconductor layers 41 and current distribution layers 51 may form a rounded corner 41A at the junction of the top surface and the side surface thereof. In contrast, in the cross-sectional view at this stage, the bottom surface of the trench H1 (i.e., the patterned first-type semiconductor material 20′) and the side surface of the trench H1 form a sharper slope structure. This structure will make the subsequent film deposition not liable to form broken lines or excessively thin thickness at the corner, and make the photoelectric characteristics of the micro light-emitting diode structure more stable.

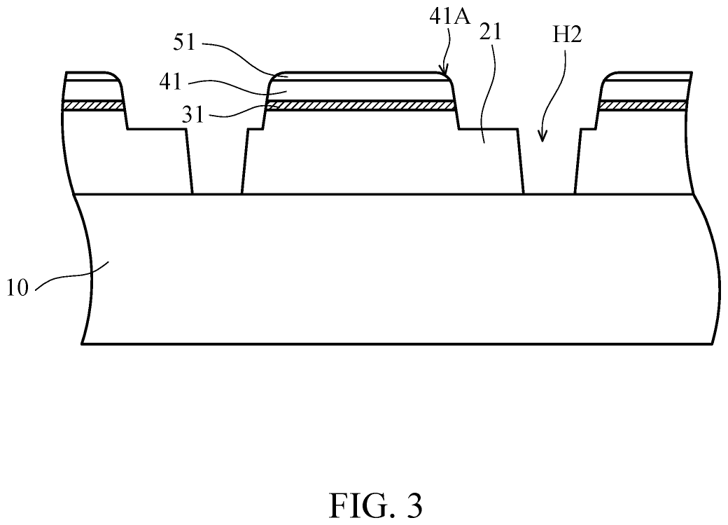

Referring to FIG. 3, a patterning process is performed to form a plurality of trenches H2 in the patterned first-type semiconductor material 20′. As shown in FIG. 3, the trenches H2 may divide the first-type semiconductor material 20′ into a plurality of first-type semiconductor layers 21. Examples of the patterning process are described above, and will not be repeated here. In particular, the trench H2 may be formed in the patterned first-type semiconductor material 20′ at the bottom of the trenches H1, so that each light-emitting layer 31, each second-type semiconductor layer 41, and each current distribution layer 51 are retracted relative to the corresponding first-type semiconductor layer 21.

Moreover, in this embodiment, the central axis of the trench H2 is separate from the central axis of the trench H1, so that the two sides of each light-emitting layer 31, each second-type semiconductor layer 41, and each current distribution layer 51 have different degrees of retraction relative to the corresponding first-type semiconductor layer 21. For example, in the cross-sectional view shown in FIG. 3, the degree of retraction of the left side of the light-emitting layer 31, the second-type semiconductor layer 41, and the current distribution layer 51 relative to the corresponding first-type semiconductor layer 21 is less than the degree of retraction of the right side of the light-emitting layer 31, the second-type semiconductor layer 41, and the current distribution layer 51 relative to the corresponding first-type semiconductor layer 21, but the present disclosure is not limited thereto. In order to more clearly illustrate the characteristics of the embodiment of the present disclosure, only one first-type semiconductor layer 21, one light-emitting layer 31, one second-type semiconductor layer 41, and one current distribution layer 51 are shown in the following drawings.

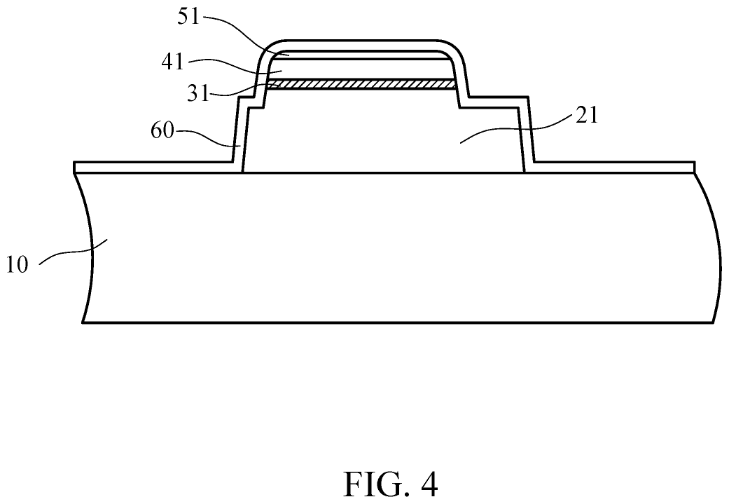

Referring to FIG. 4, an insulating material 60 is formed on the first-type semiconductor layer 21, the light-emitting layer 31, the second-type semiconductor layer 41, and the current distribution layer 51. In particular, the insulating material 60 may be formed on a portion of top surface and side surface of the first-type semiconductor layer 21, the side surfaces of the light-emitting layer 31 and the second-type semiconductor layer 41, and the top surface and side surface of the current distribution layer 51.

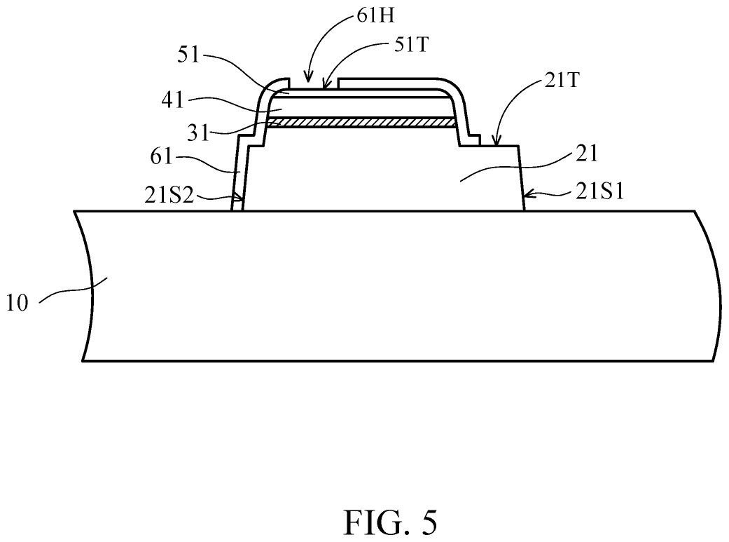

Referring to FIG. 5, a patterning process is performed to remove a portion of the insulating material 60 and form an insulating layer 61. Examples of the patterning process are described above, and will not be repeated here. In particular, as shown in FIG. 5, the insulating layer 61 is formed on the first-type semiconductor layer 21, the light-emitting layer 31, the second-type semiconductor layer 41, and the current distribution layer 51, and may include a via hole 61H that exposes a portion of the top surface 51T of the current distribution layer 51. In addition, the insulating layer 61 is also in contact with a portion of the first-type semiconductor layer 21 and exposes a portion of top surface 21T of the first-type semiconductor layer 21. In the cross-sectional view at this stage, the first-type semiconductor layer 21 has a side surface 21S1 and a side surface 21S2 opposite the side surface 21S1, and the side surface 21S1 is adjacent to the portion of top surface 21T. That is, in the embodiment shown in FIG. 5, the insulating layer 61 may cover the side surface of the light-emitting layer 31, the side surface of the second-type semiconductor layer 41, and the side surface 21S2 of the first-type semiconductor layer 21, but not cover the portion of top surface 21T and the side surface 21S1.

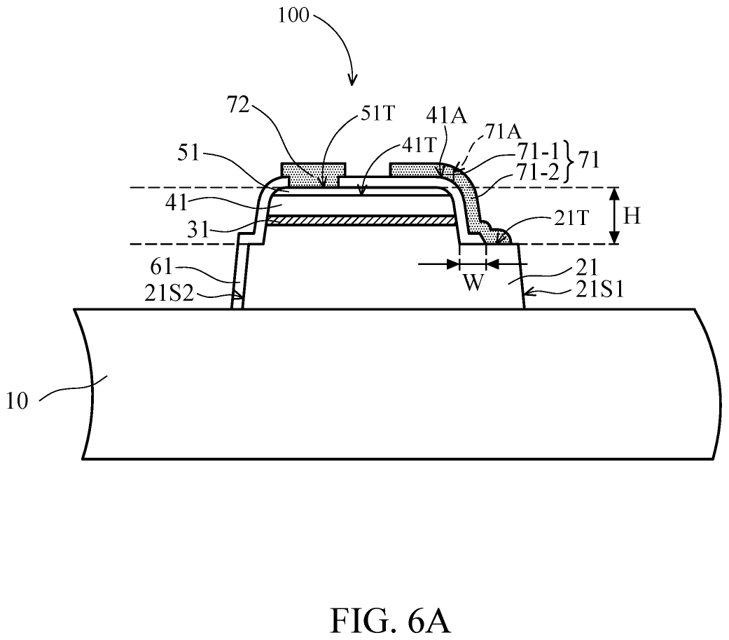

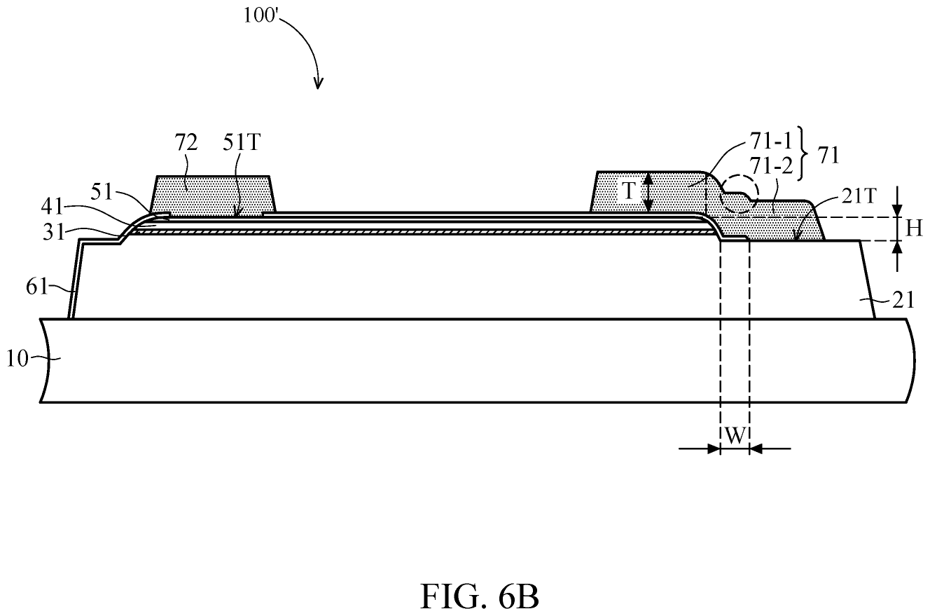

Referring to FIG. 6A, a first electrode 71 and a second electrode 72 are formed (the first electrode 71 is electrically connected to the first-type semiconductor layer 21 and the second electrode 72 is electrically connected to the second-type semiconductor layer 41) to form the micro light-emitting diode structure 100. For example, the first electrode 71 and the second electrode 72 are formed may be formed by a deposition process and a patterning process, but the present disclosure is not limited thereto. Examples of the deposition process and the patterning process are described above, and will not be repeated here.

In particular, as shown in FIG. 6A, the first electrode 71 has a first portion 71-1 disposed on the top surface 41T of the second-type semiconductor layer 41 (i.e., on the current distribution layer 51) and a second portion 71-2 connected to the first portion 71-1 and the first-type semiconductor layer 21, and the second electrode 72 is disposed on the top surface 41T of the second-type semiconductor layer 41 (i.e., on the current distribution layer 51).

As shown in FIG. 6A, the shortest distance (i.e., the vertical distance) between the top surface 51T of the current distribution layer 51 and the portion of top surface 21T of the first-type semiconductor layer 21 is H, and the width a portion of the insulating layer 61 in contact with the first-type semiconductor layer 21 is W. In some embodiments, the ratio of the width W to the distance H may be between 0.9 and 1.1 (i.e., W/H=1±0.1), but the present disclosure is not limited thereto.

In the embodiment shown in FIG. 6A, the second portion 71-2 of the first electrode 71 is in direct contact with the portion of top surface 21T of the first-type semiconductor layer 21 to be electrically connected to the first-type semiconductor layer 21, and the second electrode 72 is in direct contact with the portion of top surface 51T of the current distribution layer 51 to be electrically connected to the second-type semiconductor layer 41. As shown in FIG. 6A, the insulating layer 61 covers the side surface of the light-emitting layer 31, the side surface of the second-type semiconductor layer 41, the side surface of the current distribution layer 51, the side surface 21S2 of the first-type semiconductor layer 21, but does not cover another side surface 21S1 and the portion of top surface 21T of the first-type semiconductor layer 21. Moreover, the insulating layer 61 is also between the first electrode 71 and the side surface of the light-emitting layer 31, between the first electrode 71 and the side surface of the second-type semiconductor layer 41, and between the first electrode 71 and the side surface of the current distribution layer 51.

In some embodiments, as shown in FIG. 6A, the second portion 71-2 of the first electrode 71 is separate from the side surface 21S1 of the first-type semiconductor layer 21. That is, the second portion 71-2 of the first electrode 71 may cover the portion of top surface 21T of the first-type semiconductor layer 21, but not extend to the side surface 21S1 of the first-type semiconductor layer 21.

FIG. 6B is a partial cross-sectional view illustrating the micro light-emitting diode structure 100′ according to another embodiment of the present disclosure. Similarly, the shortest distance (i.e., the vertical distance) between the top surface 51T of the current distribution layer 51 and the portion of top surface 21T of the first-type semiconductor layer 21 is H. Moreover, in the embodiment shown in FIG. 6B, the thickness T of the first electrode 71 (and the second electrode 72) may be larger than the distance H. Therefore, (the second portion 71-2 of) the first electrode 71 may form a gap (e.g., the dashed circle in FIG. 6B), and form a rounder shape. This shape may effectively improve the bonding yield during subsequent (mass) transfer.

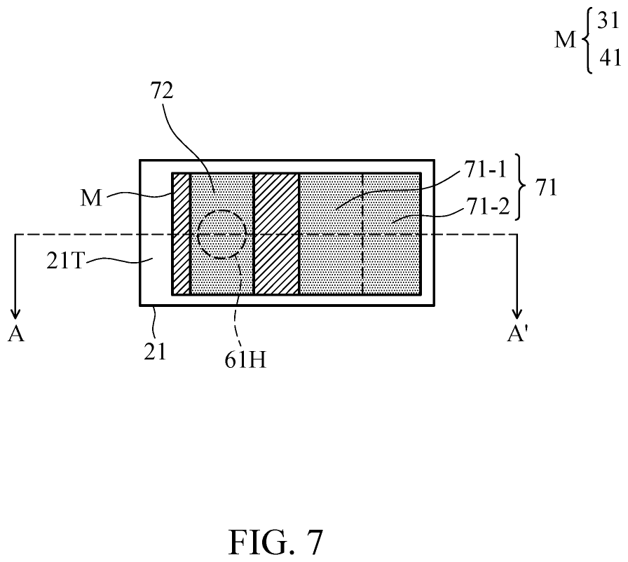

FIG. 7 is a partial top view illustrating the micro light-emitting diode structure 100 in FIG. 6A. For example, FIG. 6A is, for example, a partial cross-sectional view of the micro light-emitting diode structure 100 along line A-A′ in FIG. 7, but the present disclosure is not limited thereto. In some embodiments, FIG. 7 may also be a partial top view illustrating the micro light-emitting diode structure 100′ in FIG. 6B. Similarly, in order to more clearly illustrate the characteristics of the embodiment of the present disclosure, some components of the micro light-emitting diode structure 100 may be omitted in FIG. 7.

Referring to FIG. 7, from the top view of the micro light-emitting diode structure 100, the light-emitting layer 31 and the second-type semiconductor layer 41 may form a mesa region M, and the mesa region M may be regarded as the light-emitting region of the micro light-emitting diode structure 100. In some embodiments of the present disclosure, the area of the mesa region M is smaller than the area of the first-type semiconductor layer 21. That is, the mesa region M (the light-emitting layer 31 and the second-type semiconductor layer 41) is retracted relative to the first-type semiconductor layer 21. In more detail, the area of the mesa region M is smaller than the area of the first-type semiconductor layer 21, and the mesa region M exposes the portion of top surface 21T of the first-type semiconductor layer 21. As shown in FIG. 7, from the top view of the micro light-emitting diode structure 100, the portion of top surface 21T of the first-type semiconductor layer 21 may surround the mesa region M.

In some embodiments, as shown in FIG. 7, from the top view of the micro light-emitting diode structure 100, the area of the first portion 71-1 of the first electrode 71 may be substantially equal to the area of the second portion 71-2 of the first electrode 71. In addition, the dopant of the first-type semiconductor layer 21 may be, for example, N-type, and the dopant of the second-type semiconductor layer 41 may be, for example, P-type, but the present disclosure is not limited thereto.

The micro light-emitting diode structure in the embodiment of the present disclosure refers to a light-emitting structure with a length and width ranging from 1 μm to 50 μm and a height ranging from 1 μm to 10 μm. In some embodiments, the maximum width of the micro light-emitting diode structure may be 20 μm, 10 μm or 5 μm, and the maximum height of the micro light-emitting diode structure may be 8 μm or 5 μm.

As shown in FIG. 6A and FIG. 7, in some embodiments of the present disclosure, since the mesa region M may expose the portion of top surface 21T of the first-type semiconductor layer 21, (the second portion 71-2 of) the first electrode 71 may be connected to the portion of top surface 21T to electrically connected to the first-type semiconductor layer 21. Even if the micro light-emitting diode structure 100 is a “micro” structure, it does not need to make a plurality of aligned holes to effectively prevent short circuits. Therefore, the complexity of the manufacturing process may be reduced (e.g., the alignment accuracy may be reduced, the process of opening holes and the overall process steps may be simplified), and the overall yield of the display device using the micro light-emitting diode structure 100 may be improved.

Furthermore, the mesa region M (the light-emitting layer 31 and the second-type semiconductor layer 41) of the micro light-emitting diode structure 100 is retracted relative to the first-type semiconductor layer 21, so that the side surfaces of the light-emitting layer 31 and the second-type semiconductor layer 41 are covered by the insulating layer 61, which may effectively avoid the possibility of side leakage current prone to occur like traditional micro light-emitting diodes.

In some embodiments, as shown in FIG. 6A (or FIG. 6B), in the cross-sectional view of the micro light-emitting diode structure 100 (or 100′), the second-type semiconductor layers 41 and current distribution layers 51 may form a rounded corner 41A at the junction of the top surface and the side surface thereof (compared to the junction between the portion of top surface 21T and the side surface 21S1 of the first-type semiconductor layer 21), and (the first portion 71-1 and the second portion 71-2 of) the first electrode 71 is conformally formed on the second-type semiconductor layer 41 and the current distribution layer 51. Therefore, in the cross-sectional view of the micro light-emitting diode structure 100 (or 100′), the first portion 71-1 and the second portion 71-2 of the first electrode 71 may also form a rounded corner 71A at the junction. The rounded corner 41A formed at the junction of the top surface and the side surface of the second-type semiconductor layer 41 and the current distribution layer 51 may prevent the first electrode 71 from peeling, and the rounded corner 71A formed at the junction of the first portion 71-1 and the second portion 71-2 of the first electrode 71 may effectively reduce charge accumulation. When the micro light-emitting diode structure 100 (or 100′) is subsequently flip-chip bonded to the display backplane of the display device, the second electrode 72 and the first portion 71-1 of the first electrode 71 that are both on the second-type semiconductor layer 41 may be bonded to the display backplane, which may have a more even force, thereby improving the bonding yield.

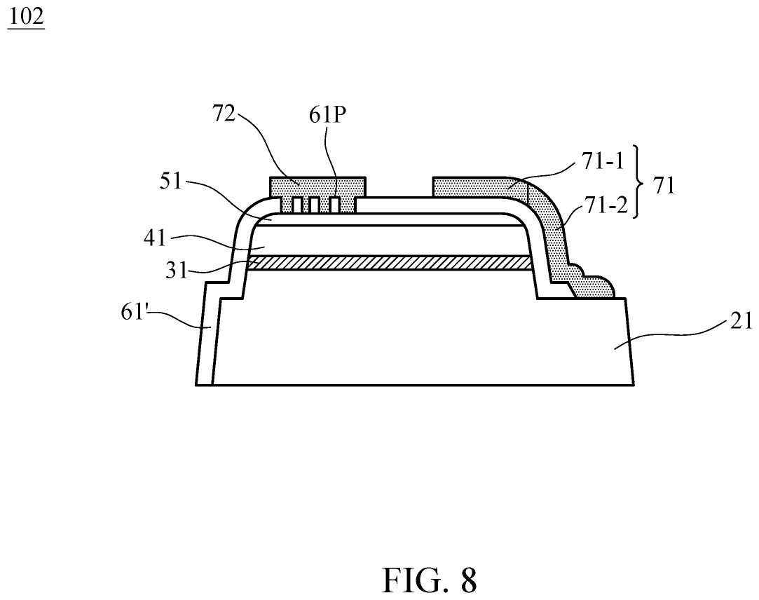

FIG. 8 is a partial cross-sectional view illustrating the micro light-emitting diode structure 102 according to another embodiment of the present disclosure. Similarly, in order to more clearly illustrate the characteristics of the embodiment of the present disclosure, some components of the micro light-emitting diode structure 102 may be omitted in FIG. 8.

The micro light-emitting diode structure 102 shown in FIG. 8 is similar to the micro light-emitting diode structure 100 shown in FIG. 6A and FIG. 7. One of the differences is that the insulating layer 61′ of the micro light-emitting diode structure 102 may include at least one insulating bump 61P disposed in the via hole 61H. As show in FIG. 8, a plurality of insulating bumps 61P may be separate from each other and disposed in the via holes 61H. The insulating bumps 61P contribute to current spreading and may reduce current accumulation in the second-type semiconductor layer 41. It should be noted that the number, shape, and position of the insulating bumps 61P are not limited to those shown in FIG. 8 and may be adjusted according to actual needs. In some embodiments, the area of the top surface 51T of the current distribution layer 51 exposed by the insulating bumps 61P that covers part of the via hole 61H exceeds 50% to ensure that the sheet resistance between the second electrode 72 and the current distribution layer 51 is not too high.

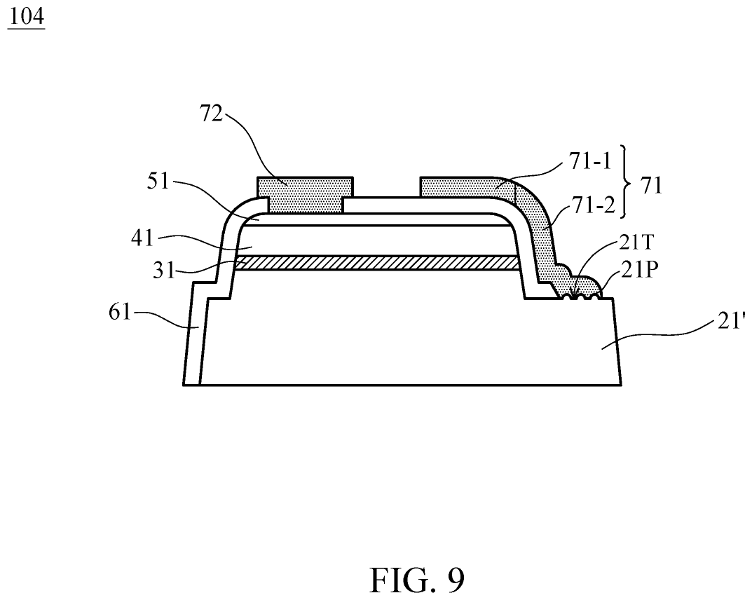

FIG. 9 is a partial cross-sectional view illustrating the micro light-emitting diode structure 104 according to still another embodiment of the present disclosure. Similarly, in order to more clearly illustrate the characteristics of the embodiment of the present disclosure, some components of the micro light-emitting diode structure 104 may be omitted in FIG. 9.

The micro light-emitting diode structure 104 shown in FIG. 9 is similar to the micro light-emitting diode structure 100 shown in FIG. 6A and FIG. 7. One of the differences is that the first-type semiconductor layer 21′ of the micro light-emitting diode structure 104 may include at least one semiconductor bump 21P. As show in FIG. 9, a plurality of semiconductor bump 21P may be disposed on the portion of top surface 21T of the first-type semiconductor layer 21′ (i.e., the top surface that is not covered by the insulating layer 61). The semiconductor bumps 21P may increase the contact area of (the second portion 71-2 of) the first electrode 71 and the first-type semiconductor layer 21′.

In some embodiments, the semiconductor bumps 21P may be formed by patterning the portion of top surface 21T of the first-type semiconductor layer 21′ (e.g., performing an etching process or a surface roughening treatment). Therefore, the material of the semiconductor bump 21P may be the same as the material of the first type semiconductor layer 21′, but the present disclosure is not limited thereto.

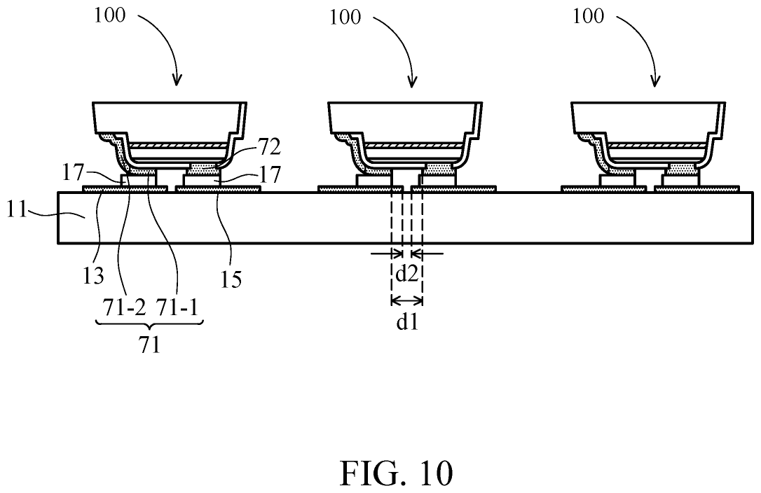

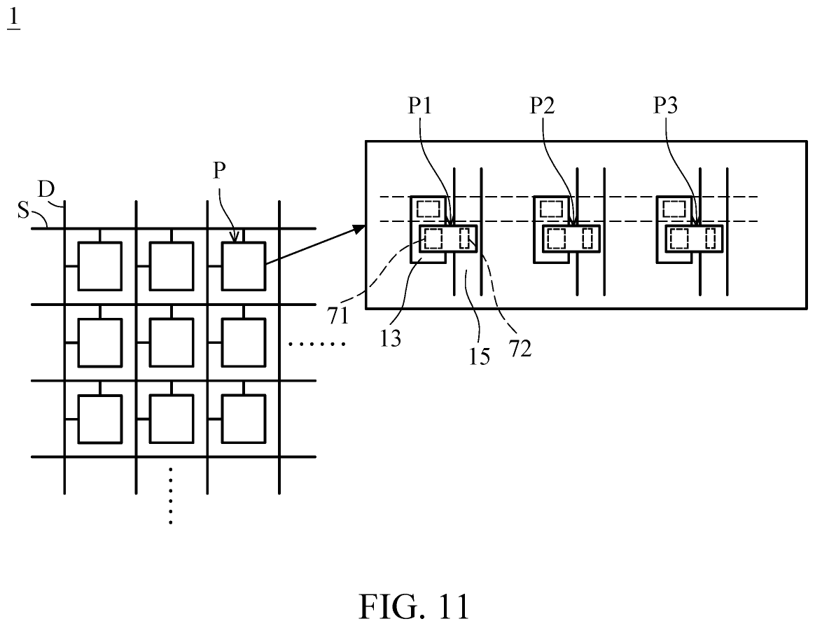

FIG. 10 is a partial cross-sectional view illustrating the micro light-emitting diode display device 1 according to one embodiment of the present disclosure. FIG. 11 is a partial circuit diagram of the micro light-emitting diode display device 1. Similarly, in order to more clearly illustrate the characteristics of the embodiment of the present disclosure, some components of the micro light-emitting diode display device 1 may be omitted in FIG. 10 and FIG. 11.

Referring to FIG. 10, the micro light-emitting diode display device 1 includes a display backplane 11. The display backplane 11 has a plurality of first connection electrodes and a plurality of second connection electrodes, and the first connection electrodes 13 and the second connection electrodes 15 may be arranged in pairs with each other. The micro light-emitting diode display device 1 also includes a plurality of micro light-emitting diode structures 100 disposed on the display backplane 11. The first connection electrode 13 and the second connection electrode 15 may be electrically connected to the first electrode 71 and the second electrode 72, respectively. In particular, a plurality of micro light-emitting diode structures 100 may be mass transferred from the substrate 10 to the display backplane 11 and bonded to the display backplane 11.

As shown in FIG. 10, the first connection electrode 13 may be electrically connected to the first portion 71-1 of the first electrode 71 via a bonding material 17 but separate from the second portion 71-2 of the first electrode 71, and the second connection electrode 15 may be electrically connected to the second electrode 72 via a bonding material 17. In some embodiments, the bonding material 17 is, for example, indium or other conductive materials. The micro light-emitting diode structure 100 may be electrically connected to the first connection electrode 13 and the second connection electrode 15 firmly through a heating and pressing process. That is, the micro light-emitting diode structure 100 is bonded to the first connection electrode 13 and the second connection electrode 15 of the display backplane 11 through the electrodes located on the mesa region M (i.e., the first portion 71-1 of the first electrode 71 and the second electrode 72), and the contact surface is flat during the bonding process, so that the micro light-emitting diode structure 100 receives a more even force and avoids splitting the bonding process.

In some embodiments, as shown in FIG. 10, the distance d2 between the first connection electrode 13 and the second connection electrode 15 is shorter than the distance d1 between (the first portion 71-1 of) the first electrode 71 and the second electrode 72, but the present disclosure is not limited thereto.

Referring to FIG. 11 at the same time, the micro light-emitting diode display device 1 includes a plurality of pixels P formed on the display backplane 11 and arranged in an array. Each row of the pixels P is controlled by, for example, scan lines S and data lines D, and the detailed circuit diagram is not shown here. Each pixel P may include a plurality of sub-pixels, such as a sub-pixel P1, a sub-pixel P2, and a sub-pixel P3. In some embodiments, the sub-pixel P1, the sub-pixel P2, and the sub-pixel P3 may respectively present red, green, and blue colors. That is, the micro light-emitting diode structure 100 in the sub-pixel P1 may be a red micro light-emitting diode, the micro light-emitting diode structure 100 in the sub-pixel P2 may be a green micro light-emitting diode, and the micro light-emitting diode structure 100 in the sub-pixel P3 may be a blue micro light-emitting diode, but the present disclosure is not limited thereto. In some other embodiments, the sub-pixel P1, the sub-pixel P2, and the sub-pixel P3 may present yellow, white, or other suitable colors.

In some embodiments, the first connection electrode 13 may be, for example, a part of the extended electrode of the common electrode line of the display backplane 11, and the second connection electrode 15 may be, for example, a part of the data line of the display backplane 11. That is, the first electrode 71 and the second electrode 72 of the micro light-emitting diode structure 100 may be electrically connected to the common electrode line and the data line of the micro light-emitting diode display device 1, respectively, but the present disclosure is not limited thereto. In some other embodiments, a plurality of micro integrated circuit (micro IC) dies disposed on the display backplane 11 of the micro light-emitting diode display device 1 may also be used to control the micro light-emitting diode structure 100 in each pixel P.

It should be noted that although a plurality of micro light-emitting diode structures 100 are provided on the display back plate 11 for description in the micro light-emitting diode display device 1 shown in FIG. 10 and FIG. 11, the present disclosure is not limited thereto. In some other embodiments, the micro light-emitting diode structure 100′ shown in FIG. 6B, the micro light-emitting diode structure 102 shown in FIG. 8, or the micro light-emitting diode structure 104 shown in FIG. 9 may also be substituted for the micro light-emitting diode structure 100 and be arranged on the display backplane 11.

In summary, from the top view of the micro light-emitting diode structure in the embodiments of the present disclosure, the mesa region (the light-emitting layer and the second-type semiconductor layer) is retracted relative to the first-type semiconductor layer to expose a portion of top surface of the first-type semiconductor layer, and the exposed portion of top surface surrounds the mesa region, so that (the second portion of) the first electrode may be connected to the exposed portion of the top surface. Therefore, there is no need to make a plurality of aligned holes to effectively prevent short circuits, thereby reducing the complexity of the manufacturing process (e.g., the alignment accuracy may be reduced, the process of opening holes may be simplified), and improving the overall yield of the display device using the micro light-emitting diode structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A micro light-emitting diode structure, comprising:
a first-type semiconductor layer;
a light-emitting layer disposed on the first-type semiconductor layer;
a second-type semiconductor layer disposed on the light-emitting layer;
a first electrode having a first portion disposed on a top surface of the second-type semiconductor layer and a second portion connected to the first portion and the first-type semiconductor layer, wherein the first electrode has a rounded corner formed at the junction between the first portion and the second portion; and
a second electrode disposed on the top surface of the second-type semiconductor layer and electrically connected to the second-type semiconductor layer;
wherein from a top view of the micro light-emitting diode structure, the light-emitting layer and the second-type semiconductor layer define a mesa region, an area of the mesa region is smaller than an area of the first-type semiconductor layer, the mesa region exposes a first top surface of the first-type semiconductor layer, and the first top surface surrounds the mesa region.

2. The micro light-emitting diode structure according to claim 1, wherein from the top view of the micro light-emitting diode structure, an area of the first portion is equal to an area of the second portion.

3. The micro light-emitting diode structure according to claim 1, wherein the second portion is in direct contact with the first top surface.

4. The micro light-emitting diode structure according to claim 1, wherein from a cross-sectional view of the micro light-emitting diode structure, the first-type semiconductor layer has a first side surface and a second side surface opposite the first side surface, the first side surface is adjacent to the first top surface, and the second portion is separate from the first side surface.

5. The micro light-emitting diode structure according to claim 4, further comprising:
an insulating layer covering a side surface of the light-emitting layer, a side surface of the second-type semiconductor layer, and the second side surface, wherein the insulating layer is in contact with a portion of the first-type semiconductor layer.

6. The micro light-emitting diode structure according to claim 5, wherein the insulating layer has a via hole, and the second electrode is electrically connected to the second-type semiconductor layer through the via hole.

7. The micro light-emitting diode structure according to claim 6, wherein the insulating layer comprises at least one insulating bump disposed in the via hole.

8. The micro light-emitting diode structure according to claim 6, further comprising:
a current distribution layer disposed between the second-type semiconductor layer and the insulating layer.

9. The micro light-emitting diode structure according to claim 8, wherein the via hole exposes a portion of a top surface of the current distribution layer, and the second electrode is in direct contact with the portion of top surface of the current distribution layer.

10. The micro light-emitting diode structure according to claim 8, wherein a ratio of a width of a portion of the insulating layer in contact with the first-type semiconductor layer to a shortest distance between a top surface of the current distribution layer and the first top surface is between 0.9 and 1.1.

11. The micro light-emitting diode structure according to claim 1, wherein the first-type semiconductor layer comprises at least one semiconductor bump disposed on the first top surface.

12. The micro light-emitting diode structure according to claim 1, wherein the light-emitting layer and the second-type semiconductor layer are retracted relative to the first-type semiconductor layer.

13. The micro light-emitting diode structure according to claim 12, wherein two sides of each of the light-emitting layer and the second-type semiconductor layer have different degrees of retraction relative to the first-type semiconductor layer.

14. The micro light-emitting diode structure according to claim 1, wherein a dopant of the first-type semiconductor layer is N-type, and a dopant of the second-type semiconductor layer is P-type.

15. A micro light-emitting diode display device, comprising:
a display backplane having a first connection electrode and a second connection electrode; and
a micro light-emitting diode structure disposed on the display backplane, comprising:
a first-type semiconductor layer;
a light-emitting layer disposed on the first-type semiconductor layer;
a second-type semiconductor layer disposed on the light-emitting layer;
a first electrode having a first portion disposed on a top surface of the second-type semiconductor layer and a second portion connected to the first portion and the first-type semiconductor layer, wherein the first electrode has a rounded corner formed at the junction between the first portion and the second portion; and
a second electrode disposed on the top surface of the second-type semiconductor layer and electrically connected to the second-type semiconductor layer;
wherein from a top view of the micro light-emitting diode structure, the light-emitting layer and the second-type semiconductor layer define a mesa region, an area of the mesa region is smaller than an area of the first-type semiconductor layer, the mesa region exposes a first top surface of the first-type semiconductor layer, and the first top surface surrounds the mesa region;
wherein the first connection electrode and the second connection electrode are electrically connected to the first electrode and the second electrode, respectively.

16. The micro light-emitting diode display device according to claim 15, wherein a distance between the first connection electrode and the second connection electrode is shorter than a distance between the first electrode and the second electrode.

17. The micro light-emitting diode display device according to claim 15, wherein the first connection electrode is electrically connected to the first portion via a bonding material and separate from the second portion, and the second connection electrode is electrically connected to the second electrode via a bonding material.

18. The micro light-emitting diode display device according to claim 15, wherein from a cross-sectional view of the micro light-emitting diode structure, the first-type semiconductor layer has a first side surface and a second side surface opposite the first side surface, the first side surface is adjacent to the first top surface, and the second portion is separate from the first side surface.

19. The micro light-emitting diode structure according to claim 15, wherein the light-emitting layer and the second-type semiconductor layer are retracted relative to the first-type semiconductor layer.

20. The micro light-emitting diode structure according to claim 19, wherein two sides of each of the light-emitting layer and the second-type semiconductor layer have different degrees of retraction relative to the first-type semiconductor layer.
